(19) United States
(12) Patent Application Publication
(10) Pub. No.: US 2010/0194313 A1
(43) Pub. Date: Aug. 5, 2010

(54) HIGH VOLTAGE ELECTRICAL CONNECTION LINE

(75) Inventors: Dominik Marcel Vaudrevange, Neuss (DE); Jakob Willi Neff, Kelmis (DE); Christof Metzmacher, La Calamine (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/679,969

(22) PCT Filed: Sep. 25, 2008
(86) PCT No.: PCT/IB08/53896

§ 371 Date: Mar. 25, 2010

(30) Foreign Application Priority Data
Oct. 1, 2007 (EP) 07117673.9

(51) Int. Cl. H05B 41/00; H05K 1/00; H05K 1/09

(52) U.S. Cl. 315/326; 174/250; 174/257

(57) ABSTRACT

The present invention relates to a high voltage electrical connection line (11), in particular for electrically connecting a gas discharge source (10) to a high voltage power source (9). The connection line is formed of a stack of two electrically conductive plates (2) separated by an electrically isolating layer (1). An electrically conductive layer (8) of a material having a higher electrical resistivity than the material of the conductive plates (2) is arranged between said isolating layer (1) and said conductive plates (2). The proposed connection line provides a higher life time when used for connecting a high voltage power source and a pulsed discharge lamp.

### FIELD OF THE INVENTION

The present invention relates to a high voltage electrical connection line, in particular for electrically connecting a gas discharge source to a high voltage power source, e.g. to a capacitor, said connection line being formed of a stack of two electrically conducting plates separated by an electrically isolating layer.

### BACKGROUND OF THE INVENTION

Gas discharge sources emitting EUV radiation and/or soft X-rays are required for example in the field of EUV lithography or metrology. A gas discharge source, as is disclosed for example in WO 2005/025280 A2, comprises at least two electrodes arranged in a discharge space and forming a gap which allows ignition of a plasma in a gaseous medium between said electrodes. For pulsed operation of such a discharge lamp, the required electrical energy can be supplied through a capacitor arrangement in which the energy is first stored and then discharged via the electrodes. Another possibility is to supply the electrical energy via a pulse compression stage directly to the electrodes. The efficiency of the lamp is strongly dependent on the electrical matching of the capacitor arrangement or of the pulse compression stage to the plasma. The electrical connection line between the capacitor arrangement or pulse compression stage and the discharge lamp is very important in this context. A connection line with lower inductivity results in a better electrical matching and therefore in a higher peak performance of the lamp.

The inductivity of the connection line of the discharge lamp is mainly determined by the distance of the two electrical conductors of this connection line. The isolating properties of known isolating materials theoretically allow very small distances. For example, the polyimide material Kapton® has a DC isolation voltage of 40 kV/mm. With a maximum voltage of a power source of 5 to 10 kV a distance between the conductors of as small as 0.25 mm should be possible when using this isolating material. In practical applications however, this small distance cannot be achieved due to the increased height of electrical fields at the edges of the conductors. The pulsed operation of the discharge lamps causes additional effects like surface discharges. The fast change of the electrical field during pulsed operation of the discharge lamp induces currents on the surface of the isolation. This effect is intensified by the non-uniform distribution of the electrical field at air gaps, edges or corners of the electrical connection lines. If this currents get too large, the isolation can be corrupted or damaged. This is a slow effect which weakens the dielectric with time. After a certain number of discharges the isolation voltage of the weakened isolation becomes too low. The result is a breakdown through the isolation which leads to a failure of the lamp.

In order to avoid such damage of the isolation by the electrical fields, it is possible to exchange the surrounding air by gases like SF₆ or to embed the connection line in oils, varnish or resin. An exchange of air by SF₆ in such an application is extensive, since the air must be removed from the whole device and the connection line must be completely relocated to a vacuum container. The use of oil is not possible when the discharge lamp is used for lithography. When sealing the connection line with varnish or resin, a later inspection of the component is made difficult or even impossible.

### SUMMARY OF THE INVENTION

It is an object of the present invention to provide a high voltage connection line for connecting a discharge lamp with a high voltage power source, which connection line provides an improved life during pulsed operation without any time consuming additional measures.

The object is achieved with the connection line according to claim 1. Advantageous embodiments of the connection line are subject matter of the dependent claims or are described in the subsequent portion of the description. Claims 10 to 12 relate to the use of such a connection line for connecting a gas discharge source with a high voltage power source.

The proposed high voltage electrical connection line is formed of a stack of two electrically conductive plates separated by an electrically isolating layer. In order to avoid surface discharges at the isolating layer, said isolating layer is coated with an electrically conductive layer of a material having a higher electrical resistivity than the material of the conductive plates. The electrically conductive layer is arranged between the isolating layer and the conductive plates without any air gaps between the isolating layer and the electrically conductive layer.

Due to this additional electrically conductive layer with an appropriate conductivity, the electrical field in air gaps or blowholes between the isolating layer and the conductive plates is reduced. Furthermore, electrically charged particles resulting from discharges between edges of the conductive plates and the surface of the isolating layer are distributed over a larger surface area of the isolating layer, so that local damages are avoided. The electrical conductivity of this electrically conductive layer must be lower than that of the electrically conductive plates. Typical values of the surface resistance of this electrically conductive layer are between 100 Ω/square and 100 kΩ/square. The thickness of the conductive layer is preferably between 100 nm and 1000 nm, more preferably less than 500 nm. The surface resistance is chosen such that local losses caused by the electrically conductive layer do not cause damages to the layer. The required surface resistance of this conducting layer cannot be achieved with pure metal layers since their resistivity is too low. Fully oxidized layers on the other hand have a too high surface resistivity. Therefore, the electrically conductive layer is preferably a partially oxidized metal layer.

In a preferred embodiment, the electrically conductive layer is a applied to the isolating layer by a sputtering process. Using a sputtering process, for example by sputtering a metal, a thin layer of several 100 nm can be applied under definite control of the oxidation of this layer. The control of oxidation and thus the control of the surface resistance of the applied layer is achieved by sputtering in an oxygen containing gas atmosphere, for example composed of a mixture of oxygen with an inert gas like argon, via the concentration of oxygen in the gas atmosphere. With this procedure, a partially oxidized metal layer with a surface resistivity required for the proposed connection line can be applied to the isolating layer.

In a preferred embodiment of the connection line the isolating layer overhangs over said conducting plates on at least two opposing sides by a definite distance, in the following called the first distance. This overhang of the isolating layer, which may be formed of a stack of isolating foils, reduces the risk of a discharge between the edges of the two conducting plates. In a further improvement of this embodiment, also the conductive layer overhangs over said contacting plates on said to opposing sides by a second distance which is smaller than said first distance. This on the one hand lowers the risk of damage of the overhanging isolating layer at the edges of the conducting plates and on the other hand reduces the risk of a discharge between the two conducting layers at their outer edges.

The two conducting plates of the connection line are preferably made of a suitable metal like copper, and may have a thickness of several millimeters. The conduction plates preferably are parallel spaced and plane, but may also have a small curvature if necessary for the application. The material used for the conducting layer may be for example partially oxidized nickel or tantalum.

These and other aspects of the invention will be apparent from and elucidated with reference to the embodiments described herein after.

### BRIEF DESCRIPTION OF THE DRAWINGS

The proposed high voltage connection line is described in the following by way of example without limiting the scope of protection as defined by the claims. The figures show:

FIG. 1 a schematic cross sectional view of a high voltage connection line according to prior art;

FIG. 2 an enlarged view of region A in FIG. 1;

FIG. 3 a schematic cross sectional view of an exemplary high voltage connection line according the invention;

FIG. 4 a schematic cross sectional view of a connection between a capacitor bank and a discharge lamp using a connection line according to the invention; and

FIG. 5 a top view on the arrangement of FIG. 4.

### DETAILED DESCRIPTION OF EMBODIMENTS

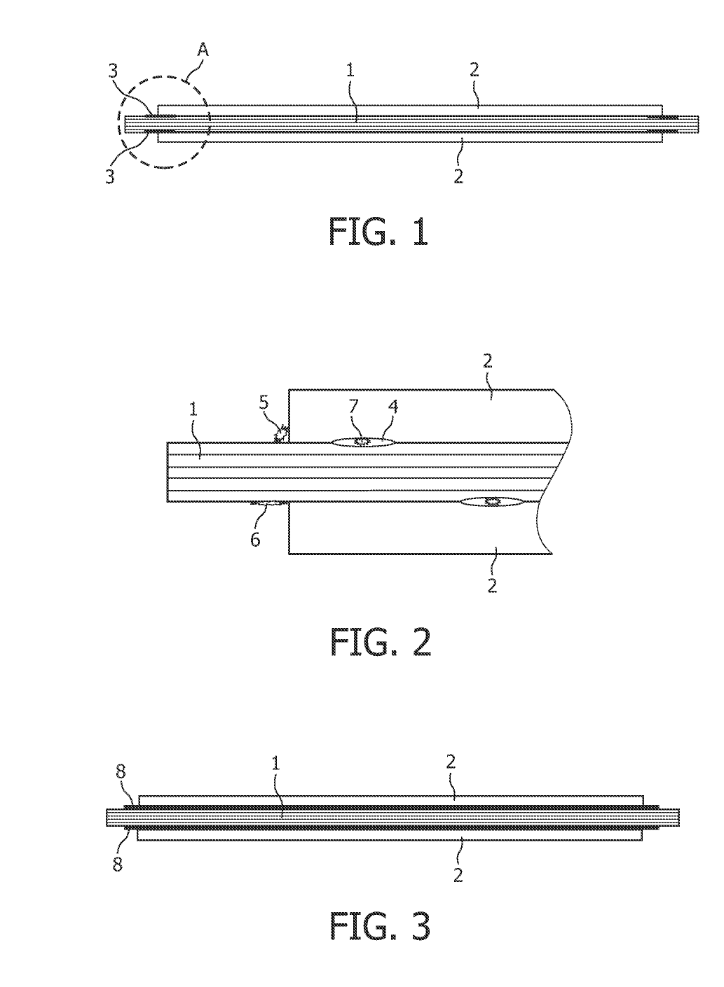

FIG. 1 shows a schematic cross sectional view of a high voltage connection line according to prior art. This connection line comprises two electrically conductive plates 2 separated by a stack of electrically isolating foils 1. When using such a connection line for connecting a high voltage power source with a gas discharge lamp, the conductive plates 2 are arranged as close as possible to one another in order to achieve a low inductivity for pulsed operation of the discharge lamp. As can be seen in FIG. 1, the isolating foils 1 overhang the conducting plates 2 on both opposing sides in order to avoid any discharge between the edges of these plates. Nevertheless, due to higher electrical fields at the edges of the conducting plates 2, electrical discharges in the surrounding air can occur. Such discharges end at the surface of the overhanging isolating foils 1. The discharges move over this surface up to some millimeters and can contract and burn small grooves in the surface over time, which damage the isolating foils 1. These regions 3 of surface discharges and damages are schematically indicated in FIG. 1.

Although the conducting plates 2 are directly connected to the isolating foils 1. Blowholes between the conducting plates 2 and the isolating foils 1 cannot be avoided during manufacturing. This is schematically indicated in FIG. 2 showing an enlarged view of region A of FIG. 1. The blowholes result in small air gaps 4 between the conductive plates 2 and the isolating foils 1. As already explained with reference to FIG. 1, at edges of the conducting plates 2 discharges 5 in the surrounding air ending on the surface of the isolating foils 1 as well as surface discharges 6 directly on the surface of the foils 1 may damage the isolating foils 1 over time. Furthermore, the electrical field inside of the small air gaps 4 may also reach an amplitude to generate a discharge 7 at these locations. All of these effects cause a reduced life time of the connection line.

In order to achieve a higher life time of such a high voltage connection line, the outer surfaces of the stack of isolating foils 1 are coated with an appropriately electrically conductive layer 8, as is schematically shown in FIG. 3. In this example, the upper and lower isolating foils of the stack are coated with a thin layer of a partially oxidized metal such that this layer separates the isolating foils 1 from the conductive plates 2. This electrically conductive layer 8 is applied by a sputtering process, sputtering the metal atoms at a controlled gas atmosphere containing argon and oxygen gas. By controlling the concentration of the oxygen in this gas atmosphere during sputtering, a defined surface resistivity of the applied layer of between 100 Ω/square and 100 kΩ/square can be achieved. In the present example, the conductive plates 2 are copper plates having a thickness of 3 mm and a lateral extension of 30 cm×30 cm. The isolating stack contains between 4 and 5 polyimide foils with a total thickness of the stack of approximately 100 μm. The isolating foils 1 exceed the conductive plates 2 on all opposing sides by approximately 1 cm. The applied conductive layer 8 also exceeds the conductive plates 2 by some millimeters, in the present example by 5 mm. This is schematically indicated in FIG. 3.

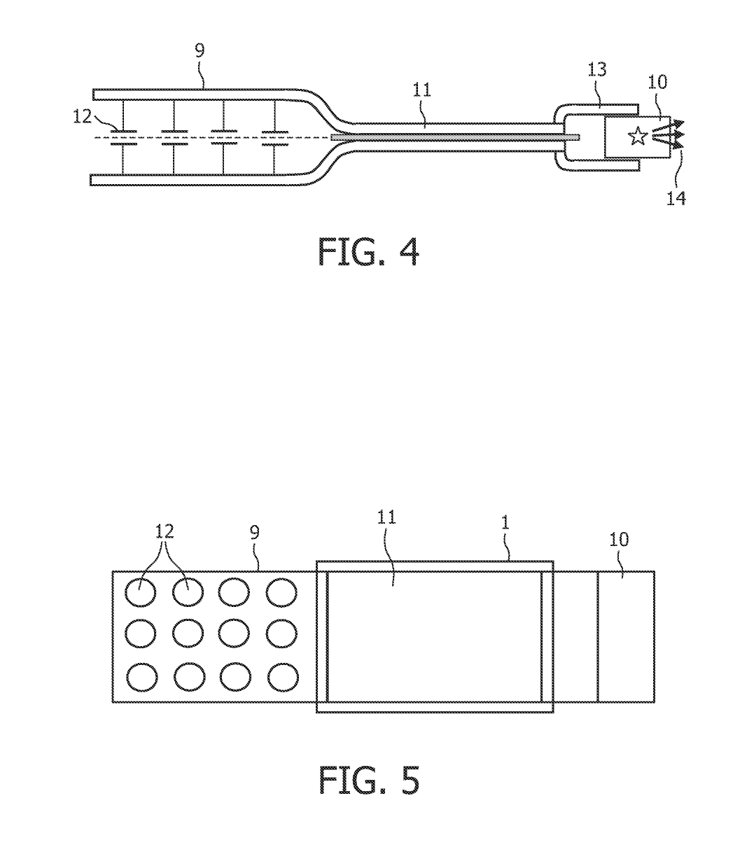

FIG. 4 shows the application of such a connection line for connecting a capacitor bank 9 as a high voltage power source with a gas discharge lamp 10. In this example, the proposed connection line 11 merges directly with the capacitor bank 9. The stack of isolating foils 1 of the connection line 11 may also extend further between the capacitor plates of capacitors 12, which is indicated by the dashed lines in FIG. 4. On the other end of the connection line 11, the conductive plates 2 of the connection line 11 are connected to the electrodes 13 of the discharge lamp 10 which emits EUV radiation 14 through the electrical discharge.

FIG. 5 shows a top view of the arrangement of FIG. 4. In this top view the array of capacitors 12 of the capacitor bank 9 as well as the connection line 11 with its overhanging stack of isolating foils 1 can be recognized. The inductivity of the connection line 11 is proportional to its length between capacitor bank 9 and gas discharge lamp 10, proportional to the distance between its conducting plates 2, which is given by the thickness of the stack of isolating foils 1, and inversely proportional to its width. Therefore, in order to get a low inductivity of the connection line 11, it is necessary to select the thickness of the isolating stack as small as possible. This is achieved by using several very thin isolating foils, for example made of Kapton®.

With the proposed construction of the connection line 11 having appropriately conducting layers 8 between the stack of isolating foils 1 and the conductive plates 2, the formation of discharges in air at the edges of the conductive plates 2 or in small air gaps 4 between the conductive plates 2 and the isolating foils 1 as well as the formation of surface discharges at the surface of the isolating foils 1 is strongly reduced. This leads to a lower risk of damage of the foils by such discharges and therefore to a significantly enhanced life time of the connection line.

While the invention has been illustrated and described in detail in the drawings and forgoing description, such illustration and description are to be considered illustrative or exemplary and not restrictive, the invention is not limited to the disclosed embodiments. The different embodiments described above and in the claims can also be combined. Other variations to the disclosed embodiments can be understood and effected by those skilled in the art in practicing the claimed invention, from a study of the drawings, the disclosure and the appended claims. For example, the proposed connection line is not limited to the use of several isolating foils as the isolating layer. This isolating layer may also be formed. for example, of only one foil or of a coating on one of the conductive plates. Furthermore, the conductive plates of the connection line may have other dimensions as those exemplary indicated in the description and embodiments.

In the claims, the word “comprising” does not exclude other elements or steps, and the indefinite article “a” or “an” does not exclude a plurality. The mere fact that measures are recited in mutually different dependent claims does not indicate that a combination of these measures can not be used to advantage. Any reference signs in the claims should not be construed as limiting the scope of these claims.

### LIST OF REFERENCE SIGNS

1 stack of isolating foils
2 conductive plates
3 region of surface discharges and damages
4 air gaps
5 discharge between plate edge and foil
6 surface discharge directly on the foil
7 discharge in air gaps
8 electrically conductive layer
9 capacitor bank
10 discharge lamp
11 connection line
12 capacitors
13 electrodes
14 EUV radiation

1. A high voltage electrical connection line for electrically connecting a gas discharge lamp to a high voltage power source, said connection line being formed of a stack of two electrically conductive plates separated by an electrically isolating layer, wherein an electrically conductive layer comprising a material having a higher electrical resistivity than the material of the conductive plates is arranged between said isolating layer and said conductive plates.

2. The connection line according to claim 1, wherein said isolating layer extends beyond said conductive plates on at least two opposing sides by a first distance.

3. The connection line according to claim 2, wherein said conductive layer extends beyond said conductive plates on said at least two opposing sides by a second distance which is smaller than said first distance.

4. The connection line according to claim 1, wherein said electrically conductive layer is applied to said isolating layer.

5. The connection line according to claim 1, wherein said conductive layer has a surface resistance of between 100 Ω/square and 100 kΩ/square.

6. The connection line according to claim 1, wherein said conductive layer is formed by sputtering.

7. The connection line according to claim 6, wherein said conductive layer is formed of a partially oxidized metallic layer.

8. The connection line according to claim 1, wherein said conductive layer has a thickness of between 100 and 1000 nm.

9. The connection line according to claim 1, wherein said isolating layer is formed of a stack of isolating foils.

10. A gas discharge lamp for generating EUV radiation and/or soft X-rays, having at least two opposing electrodes for generating a gas discharge, said electrodes being connected via the connection line according to claim 1 to a high voltage power source.

11. The gas discharge lamp according to claim 10, wherein said high voltage power source comprises a capacitor bank.

12. The gas discharge lamp according to claim 11, wherein said conductive plates of said connection line are directly connected to capacitor plates of capacitors of the capacitor bank.
